(19) United States
(12) Patent Application Publication
(10) Pub. No.: US 2013/0228916 A1
(43) Pub. Date: Sep. 5, 2013

(54) TWO-SOLDER METHOD FOR SELF-ALIGNING SOLDER BUMPS IN SEMICONDUCTOR ASSEMBLY

(71) Applicant: Kazuaki Mawatari, Beppu-city (JP)

(72) Inventor: Kazuaki Mawatari, Beppu-city (JP)

(73) Assignee: TEXAS INSTRUMENTS INCORPORATED, Dallas, TX (US)

(21) Appl. No.: 13/411,116

(22) Filed: Mar. 2, 2012

(51) Int. Cl. H01L 23/498; B23K 31/02

(52) U.S. Cl. 257/737; 228/180.22; 257/E23.068

(57) ABSTRACT

A semiconductor device (100) comprising a semiconductor chip (101) assembled on a substrate (130) by solder joints; the chip and the substrate having a first set of contact pads (110, 140) of a first area, respective pads vertically aligned and connected by joints (160) made of a first solder having a first volume and a first melting temperature; and the chip and the substrate having a second set of contact pads (122, 150) of a second area, respective pads vertically aligned and connected by joints (170) made of a second solder having a second volume and a second melting temperature, the first melting temperature being lower than the second melting temperature.

### FIELD OF THE INVENTION

The present invention is related in general to the field of semiconductor devices and processes, and more specifically to the structure and fabrication method self-aligning two-solder bumps in assembly of low bump-count fine-pitch semiconductor devices.

### DESCRIPTION OF RELATED ART

Since IBM first introduced a soldering technology called Controlled Collapse Chip Connection (commonly known as C4) about four decades ago, many advantages of this technology have been realized: batch assembly, self-aligning capability, high interconnection density, high yield, and low cost. The self-alignment mechanism in particular is important for semiconductor devices with high bump count and fine bump pitch.

In the solder self-alignment mechanism, the molten solder wets the metal pad and forms a solder joint; however, this joint may be misaligned. The restoring surface tension, a force acting on the unit length of the surface (Newton per meter, kg·s⁻²), is proportional to the misalignment and will drive the misaligned solder joint to become a well aligned joint in order to minimize the energy of the assembly. Since the minimum surface energy is reached for a sphere, the surface tension will work to obtain a spherical surface shape (the surface energy and the load from the chip are two terms in the energy function).

Challenges for the C4 technology have arisen from technology requirements to satisfy recent market trends such as handheld products, miniaturized controls, and automotive and medical electronic products. Among the challenges are area arrays of solder joints with small footprint, large numbers of low-inductance connections, and connections to a substrate aligned to a precision of better than 1 micrometer. Quasi-static and dynamic models have been published (for instance by S. K. Patra and Y. C. Lee, Department of Mechanical Engineering, University of Colorado, Boulder, Colo., 1990, 1991, 1995) to optimize design parameters for self-aligning flip-chip solder connections. These models show that the alignment accuracies are related to design parameters such as pad size, joint height, solder volume, surface tension property, vertical loading, and initial misalignment, but that the restoring force becomes small when the chip is close to the well-aligned position.

As examples for a chip, solder joints and a substrate, the design guidelines resulting from the models show that the maximum restoring force for misaligned joints occurs when the solder joint height is equal to the height of a spherical joint; that the joint height collapses substantially just after melting then moves up a little during the self-alignment; and that a chip, put on the solder joints, presses the joints down and thus reduces the restoring force. As further guidelines, for a given assembly area, fine pitch connections (and thus a higher number of joints) generate a much larger restoring force large pitch connections (and smaller number of joints); a smaller solder volume results in a larger restoring force; for given aspect ratio of solder joints, smaller joints generate slightly larger restoring forces than bigger joints; and convex solder joints push a chip up, while concave solder joints pull a chip down.

A dynamic model further shows that during reflow the horizontal component of the surface tension, the restoring force, has the acceleration of the chip acting in the direction of reduced misalignment, but an accompanying viscous damping force in the direction against the motion. The damping coefficient is linearly dependent on the pad area (square meter) and the dynamic viscosity (pascal second) of the solder, but the viscosity properties are so far not known over the entire reflow temperature range.

### SUMMARY OF THE INVENTION

When applicant realized that the market trend for handheld, medical and automotive electronic products requires semiconductor devices in low bump-count and fine-pitch packages, he recognized that placement accuracies of less than 25% of the pad size face a challenge in flip-chip assembly: For the self-alignment of solder joints, the viscous damping force, which acts against the motion direction of self-alignment, is remaining high for low bump count. Consequently, a practical low-cost method must be identified to reduce viscous damping and maximize the restoring force in misalignment, thus effectively compensating alignment inaccuracies.

Applicant saw that viscous damping results from friction of the molten solder and that this friction can be reduced by increasing the temperature, but that on the other hand, too much temperature increase would initiate a hard-to-control run-away of the solder.

Applicant solved the problem of reducing the viscous solder damping in a controlled range, when he discovered that precise self-alignment of solder joints in low-count and fine-pitch electrical bumps can be achieved by a practical and low-cost two-solder method: In addition to the electrically active function bumps, electrically inactive auxiliary alignment bumps are introduced (on the chip or on the substrate), which have a first solder alloy with a first eutectic temperature lower than the eutectic temperature of a second solder alloy applied for the electrically active function bumps.

After the auxiliary alignment bumps melt at the lower first eutectic temperature and collapse, they form auxiliary joints. While the temperature is raised to the higher eutectic temperature of the second alloy, the viscosity of these auxiliary joints, and thus the viscous damping, is lowered, allowing the auxiliary joints to fully self-align and bring the electrically active bumps in favorable contact. As soon as the eutectic temperature of the electrically active bumps is reached, liquefying the second solder alloy, the active bumps augment the restoring force of the auxiliary bumps and are automatically aligned to form good connection joints. The temperature increase is stopped at the liquidus temperature of the second solder alloy so that the viscosity of the first alloy will not run away and the cooling cycle can begin.

When the size of the chips permits, it is more efficient to design the auxiliary alignment bumps with a larger contact area and a larger solder volume than the electrically active bumps. After solidification, large auxiliary bumps also allow the auxiliary joints to act as effective heat spreaders of the operating assembled device, thereby improving the thermal characteristics of the package.

A few melting temperature examples for successfully paired first and second solder alloys include the following: For auxiliary bumps, eutectic binary tin-silver alloy at 221° C., for function bumps, tin 100 alloy at 232° C.; for auxiliary bumps, eutectic binary tin-bismuth alloy at 139° C., for function bumps, eutectic binary tin-silver alloy at 221° C.; for auxiliary bumps, eutectic binary tin-indium alloy at 120° C., for function bumps, eutectic binary tin-silver alloy at 221° C.

### BRIEF DESCRIPTION OF THE DRAWINGS

FIG. 1 illustrates a cross section of a semiconductor chip attached to a substrate, the chip having function bumps with high-melting solder and alignment bumps with low-melting solder; in addition, the alignment pads have larger areas than the function pads.

FIG. 2 is time-temperature diagram depicting the reflow sequence of the low-melting solder and the high-melting solder.

FIGS. 3 to 6 depict certain process steps of the assembly flow for solder alloys of two different reflow temperatures.

FIG. 3 shows a cross section of the misplacement of the chip relative to the substrate pads; the chip alignment bumps with the solder of lower melting temperature touch their respective substrate pads, while the chip function bumps with the solder of higher melting temperature do not touch their respective substrate pads.

FIG. 4 illustrates a cross section of the chip still misaligned relative to the substrate pads, when the temperature to liquefy the low-melting solder is reached. The load of the chip and the concave solder joints pull the chip down so that the (still solid) function bumps touch the respective substrate pads.

FIG. 5 shows a cross section of the chip with the (still solid) chip function bumps fully aligned with their respective substrate pads, after increasing temperature has reduced the viscosity, and thus the viscous damping, of the low-melting solder.

FIG. 6 depicts a cross section of the assembled chip with fully aligned function bumps, when the temperature has been increased to melt the solder of the function bumps.

### DETAILED DESCRIPTION OF THE PREFERRED EMBODIMENTS

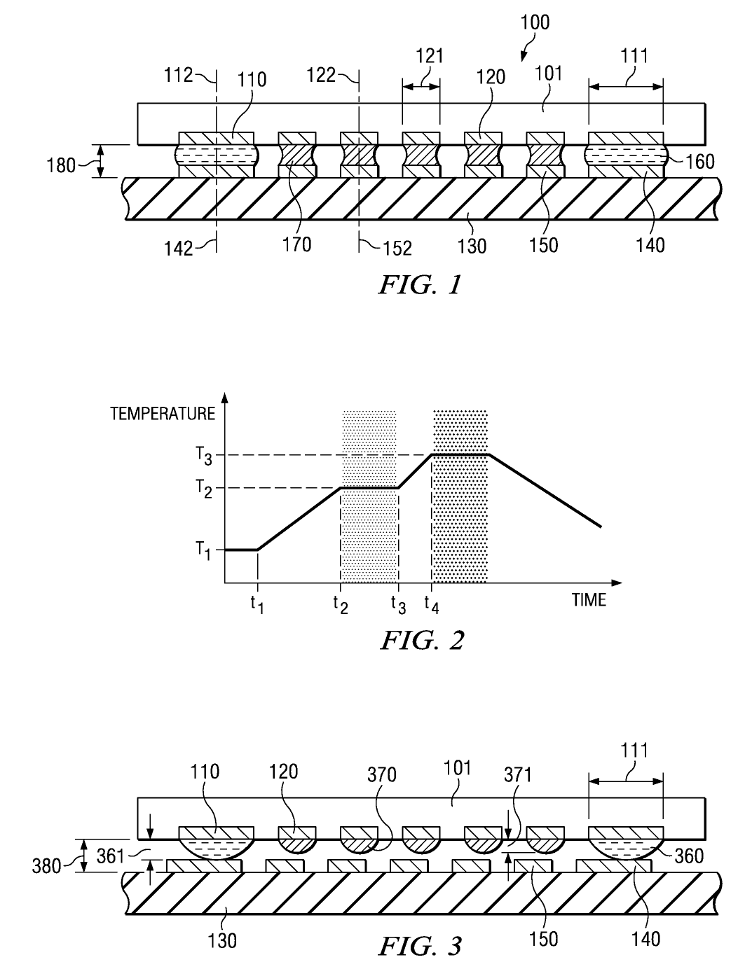

FIG. 1 illustrates an exemplary embodiment of an assembled device generally designated 100. Device 100 includes a semiconductor chip 101 with a first set of metallic contact pads 110 and a second set of metallic contact pads 120. The first contact pads 110 have a first area, indicated in FIG. 1 by linear dimension 111, and may be electrically inactive; pads 110 are herein referred to as alignment pads. Second contact pads 120 have a second area, indicated in FIG. 1 by linear dimension 121, and are electrically active; pads 120 are herein referred to as function pads. Preferably, the first area is greater than the second area, but in other embodiments they may be equal. The first and the second contact pads are made of a metal such as copper or aluminum and have a surface metallurgically configured to be wettable and solderable. As an example, the contact pad surfaces may include a layer of nickel followed by a layer of palladium and an outermost layer of gold.

Device 100 further includes a substrate 130 with metallic contact pads positioned in mirror image to the chip contact pads: a first set of contact pads 140 include pads with position and size of the alignment pads 110; a second set of contact pads 150 include position and size of the function pads 120. The first and second contact pads of the substrate are made of a metal such as copper, aluminum, iron, or graphite, and have a surface metallurgically configured to be wettable and solderable. For example, the contact pad surfaces may include a flash of gold.

As FIG. 1 shows, respective chip contact pads and substrate contact pads are connected by solder joints. The solder joints connecting the first set of contact pads 110 and 140 are designated 160 and have a first volume and a first melting temperature; the solder of these joints is herein referred to as first solder. The solder joints connecting the second set of contact pads 120 and 150 are designated 170 and have a second volume and a second melting temperature; the solder of these joints is herein referred to as second solder. The first melting temperature is lower than the second melting temperature, and the first joint volume may be larger than the second joint volume.

Since the first melting temperature is lower than the second melting temperature, the solders for joints 160 and 170 have to be coordinated. A few examples of suitable solders 160 and 170 include the following combinations:

For selecting as first solder the binary eutectic tin-silver alloy (melting temperature 221° C.), the second solder is preferably tin 100 alloy (melting temperature 232° C.). Among non-binary tin-silver alloy options, the following alloy may be mentioned: 1.2 weight % silver, 0.5 weight % copper, 0.05 weight % nickel, 98.25 weight % tin (melting temperature of 220.5° C., liquidus temperature of 225° C.); and the alloy 3.0 weight % silver and 97 weight % tin (melting temperature 217° C. and liquidus temperature 220° C.).

For selecting as first solder the binary eutectic tin-bismuth alloy (melting temperature 139° C.), the second solder is preferably the binary eutectic tin-silver alloy (melting temperature 221° C.).

For selecting as first solder the binary eutectic tin-indium alloy (melting temperature 120° C.), the second solder is preferably binary eutectic tin-silver alloy (melting temperature 221° C.).

Since the use of the binary eutectic tin-lead alloy (melting temperature 183° C.) is being phased out for environmental reasons, other options, especially for the first solder, include the binary eutectic tin-zinc alloy (melting temperature 198.5° C.), the binary eutectic tin-gold alloy (melting temperature 217° C.), and the binary eutectic tin-copper alloy (melting temperature 227° C.).

After the solder joints are established and solidified, embodiment 100 of FIG. 1 shows the contact pads 110 and 120 of chip 101 aligned with the respective contact pads 140 and 150 of substrate 130. The alignment is expressed in FIG. 1 by continuous center lines. The center lines 112 of pads 110 and the center lines 142 of pads 140 are straight lines continuous through solder joints 160; the center lines 122 of pads 120 and the center lines 152 of pads 150 are straight lines continuous through solder joints 170.

As FIG. 1 indicates, first contact pads 110 have a first area, based on linear dimension 111, larger than the second area of second contact pads 120, based on linear dimension 121. Furthermore, the volume of solder for joints 160 is greater than the volume of solder for joints 170. In other embodiments, however, the area of the first terminal pads is the same as the area of the second terminal pads; in addition, the volume of solder for the first terminals is the same as the volume of solder for the second terminals. The reason for the preference of a larger area for contact pads 110 compared to the area of contact pads 120, and a larger volume of solder 160 compared to the volume of solder 170, is the easy and quick assembly manufacturability, which permits an initial misalignment between chip 101 and substrate 130 to be corrected by the process flow of the flip-chip assembly (see below).

It should be noted that large-size alignment pads, even when they are not electrically used, can operate as effective heat spreaders during device operation.

After the assembly is completed, gap 180 spacing chip 101 from substrate 130 is uniform for device 100, since the reflowed solder 160 for the alignment pads and solder 170 for the function pads have the same final height.

When the solder bump of a misaligned contact pad 110 touches the respective substrate pad 140 and is then brought to the melting temperature (for more detail about the method see description below), the molten solder wets the metal surface of pad 140 and may form a misaligned solder joint. As described by S. K. Patra and Y. C. Lee (Department of Mechanical Engineering, University of Colorado, Boulder, Colo., 1990, 1991, 1995) and other researchers, the restoring process of alignment derives from the principle of energy minimization, when the restoring force, arising from the shear force of surface tension, is compared to the viscous damping force, arising from the friction of the molten solder, and to the chip inertia. The energy function contains essentially the surface energy and the load from the chip. The restoring force is proportional to the misalignment and becomes smaller when the chip is close to the well-aligned position. Model calculations have shown that the restoring force is maximized when the solder joint height is equal to the height of a spherical joint; in contrast, the chip weight is pressing the liquefied joint down and thus reduces the restoring force. This undesirable effect can be reduced when devices may have numerous joints; however for devices with low numbers of joints another parameter is needed for relief.

According to the invention, the improving effect is based on the gradual reduction of solder viscosity by continued increase of the temperature beyond the melting temperature. As a precaution against any risk of solder run-away, however, the viscosity reduction needs to be safely stopped; applicant found a practical way by introducing a second solder with a second, higher melting temperature for the joints of the function pads.

Model calculations show that a smaller solder volume will result in a larger restoring force, and a fine solder pitch design generates a larger restoring force than a large solder pitch design. These results are valuable guidelines for size and layout of the second set of contact pads of chip and substrate, which are the electrically active function pads. In contrast, for size and solder volume of the first set contact pads, which serve the solder alignment, the dominant guidelines are enhanced manufacturability including forgiving process windows, fast throughput time, and low-cost fabrication equipment. These requirements call for relatively large-size alignment pads, which are easily visible and controllable. As a rule of thumb, the alignment pads should preferably not be substantially smaller than the electrically active function pads.

During reflow, the restoring force of a chip misalignment acts in the direction for reducing the misalignment and moving the chip in the direction of reduced misalignment. The magnitude of the restoring force is directly proportional to the misalignment. However, the accompanying viscous damping force is always in the direction against the corrective motion. The viscous damping is proportional to the contact pad area and the viscosity of the molten solder. Consequently, the viscous damping force can be reduced by reducing the solder viscosity, which can be accomplished by increasing the temperature of the molten solder. This effect is exploited by the introduction of solders with two different melting temperatures and the process flow as displayed in FIGS. 2 to 6.

FIG. 2 shows a generic temperature-time diagram for the assembly of a semiconductor chip 101 on a substrate 130, when solders with two different melting temperatures as used; the initial arrangement for assembly is displayed in FIG. 3. The time of the heating and cooling cycle is plotted on the abscissa of FIG. 2 and the solder melting temperatures on the ordinate. T₁ is the ambient temperature, for example 23° C., T₂ the solder melting temperature of the first set of contact pads (alignment pads 110), for example 139° C. of eutectic tin-bismuth alloy, and T₃ the solder melting temperature of the second set of contact pads (function pads 120), for example 221° C. for eutectic tin-silver alloy.

As illustrated in FIG. 3, the process flow starts by providing a semiconductor chip 101 with a first set of contact pads 110 with linear dimension 111. The pad area is covered by first solder bumps 360 having a first melting temperature and a first volume. As indicated in FIG. 3, the first solder has been reflowed and the first bumps have a convex surface contour reaching a first height 361. Chip 101 further has a second set of contact pads 120 covered by second solder bumps 370 having a second melting temperature and a second volume. As indicated in FIG. 3, the second solder has been reflowed and the second bumps have a convex surface contour reaching a second height 371. The first melting temperature is lower than the second melting temperature. In addition, the first solder volume may be greater than the second solder volume, and the first bump height 361 is preferably greater than the second bump height 371.

It should be noted that the term bump is to be understood in the sense of solder cluster rather than in a geometrical sense. It should further be stresses that all considerations and method steps to be discussed remain valid for devices, in which the solder materials are applied to the substrate pads rather than to the chip pads, and for devices, which use solder layers rather than solder bumps.

Next, a substrate 130 is provided, which has a first set of solderable contact pads 140 and a second set of solderable contact pads 150. Contact pads 140 have preferably the same linear dimension as chip alignment pads 110. These substrate pads are located in mirror image to the respective chip contact pads.

In the next process step, chip 101 is placed over substrate 130 so that the alignment solder bumps 360 approximately line up with the respective substrate contact pads 140; as an example, the alignment accuracy may be 25%. Chip 101 is then lowered so that alignment solder bumps 360 touch the respective first set pads 140 of the substrate. This step is depicted in FIG. 3 and also indicated in FIG. 2 as time t₁ at temperature T₁. Gap 380 spacing chip 101 from substrate 130 is controlled by the height of chip alignment bumps 360. As the figure shows, at this process step chip solder bumps 370 may not be in touch with their respective substrate contact pads 150.

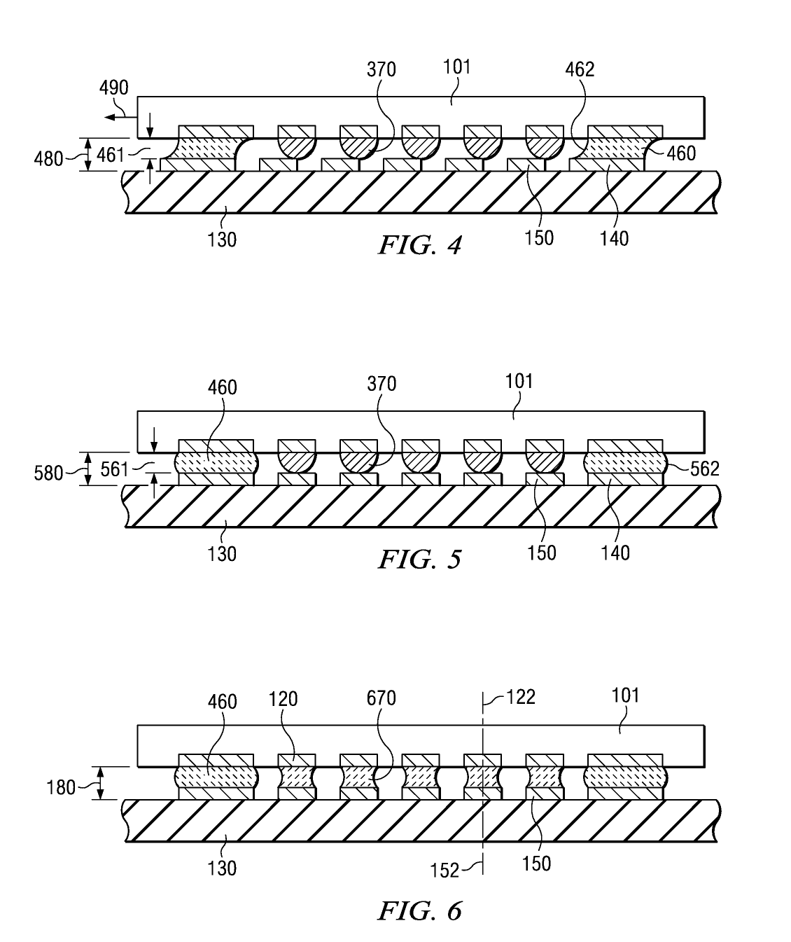

FIG. 4 illustrates the next process step. Thermal energy is provided to increase the temperature from T₁ to the first melting temperature T₂, which is reached at time t₂ (see FIG. 2). Alignment solder bumps 360 are melting and height 361 of the alignment bumps 360 is collapsing under the weight of chip 101 so that the solid second solder bumps 370 touch the respective substrate pads 150, although still misaligned. Gap 480 spacing chip 101 from substrate 130 is controlled by the height of chip function bumps 370.

The first solder of the alignment bumps is wetting the area of first substrate contact pads 140, forming the distorted joints 460 of height 461. The meniscus 462 of the joint surfaces reflects the misalignment of the solder joints. As a consequence, the restoring force of surface tension starts to drive chip 101 in the direction indicated by arrow 490 in order to minimize the energy of the assembly; this motion gradually corrects the misaligned joints into properly aligned joints. As stated above, the restoring force is accompanied by the viscous damping force, which is in the direction against direction 490. After the time interval between t₂ and t₃, a major portion of the misalignment correction is reached at time t₃.

This phase of self-alignment is shown in FIG. 5. The restoring force has moved chip 101 relative to substrate 130 so that function bumps 370 are approximately centered on substrate contact pads 150. Based on the aspect ratio of first solder and substrate pads 140, the meniscus contours 562 of the liquid alignment solder become convex, causing the height 561 of the aligned joint to move slightly higher compared to height 461 of the misaligned joint. Consequently, gap 580 spacing chip 101 from substrate 130 is slightly greater than gap 480.

Since the restoring force of solder 460 is proportional to the misalignment, controlling the final alignment (the remaining chip movement) requires an increase of the restoring force by reducing the viscous damping. This portion of the correction is achieved in the time interval from t₃ to t₄ (see FIG. 2), when thermal energy is provided to increase the temperature beyond T₂ and thus reduce the viscosity of the first solder.

In order to avoid a runaway of the first solder, the phase of viscosity reduction is stopped, when, at time t₄, the melting temperature T₃ of the second solder bumps 370 attached to the chip function bumps 120 is reached. As illustrated in FIG. 6, at the temperature T₃ the second solder bumps, now designated 670, are melting and wetting the second substrate contact pads 150. While the temperature is at T₃ in the time interval from t₄ to t₅, the joints with the second solder are under the influence of surface tension, acquiring concave (or convex) surface contours and incrementally support the final self-aligning of the molten second bumps. As a result, the center lines 122 of the chip function pads 120 and the center lines 152 of the second substrate pads 150 are aligned, and the profile of the second joints 670 becomes axi-symmetric. The gap spacing chip 101 from substrate 130 acquires its final value 180, which is retained until temperature cool-down solidifies all solder joints, see FIG. 1.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the two-step self-aligning features based on the different melting temperatures of the first and second solders are applicable to devices with symmetrical bump arrays and to devices with asymmetrical bump arrays; and to devices with numerous solder joints and devices with small numbers of solder joints. The advantage of alignment joints is particularly evident for fine pitch solder joint devices.

As another example, the two-step self-aligning features based on the different melting temperatures of the first and second solders are applicable to devices with symmetrical bump arrays and to devices with asymmetrical bump arrays; and to devices with numerous solder joints and devices with small numbers of solder joints. The advantage of alignment joints is particularly evident for fine pitch solder joint devices.

As another example, there may be any number of alignment pads, and that the pads may in any location and distribution.

It is therefore intended that the appended claims encompass any such modifications or embodiments.

1. A semiconductor chip comprising:
a first set of contact pads having a first area covered by solder bumps of a first volume and a first melting temperature; and
a second set of contact pads having a second area covered by solder bumps of a second volume and a second melting temperature, the first melting temperature being lower than the second melting temperature.

2. The device of claim 1 wherein the first pad area is greater than the second pad area, and the first bump volume is greater than the second bump volume.

3. The device of claim 1 wherein the first pad area is the same as the second pad area, and the first bump volume is the same as the second bump volume.

4. A semiconductor device comprising:
a semiconductor chip assembled on a substrate by solder joints;
the chip and the substrate having a first set of contact pads of a first area, respective pads vertically aligned and connected by joints made of a first solder having a first volume and a first melting temperature; and
the chip and the substrate having a second set of contact pads of a second area, respective pads vertically aligned and connected by joints made of a second solder having a second volume and a second melting temperature, the first melting temperature being lower than the second melting temperature.

5. The device of claim 4 wherein the first pad area is greater than the second pad area, and the first joint volume is greater than the second joint volume.

6. The device of claim 4 wherein the first pad area is the same as the second pad area, and the first joint volume is the same as the second joint volume.

7. The device of claim 4 wherein first and second solders are selected from a group of suitable pairs including: A pair with first solder being eutectic binary tin-silver alloy (melting temperature 221° C.) and second solder being tin 100 alloy (melting temperature 232° C.); a pair with first solder being eutectic binary tin-bismuth alloy (melting temperature 139° C.) and second solder being eutectic binary tin-silver alloy (melting temperature 221° C.); a pair with first solder being eutectic binary tin-indium alloy (melting temperature 120° C.) and second solder being eutectic binary tin-solder alloy (melting temperature 221° C.).

8. A method for fabricating a semiconductor device comprising the steps of:
providing a semiconductor chip having a first set of solder bumps of a first melting temperature and a second set of solder bumps of a second melting temperature, the first melting temperature being lower than the second melting temperature;
placing the chip onto a substrate so that the first solder bumps touch the substrate;
raising the temperature for melting the first solder bumps, thereby self-aligning the first solder bumps and lowering the chip, causing the second solder bumps to touch the substrate; and
further raising the temperature to reduce the viscosity of the first solder, enhancing first-bump self-alignment, and to melt the second solder, thereby allowing the second solder bumps to self-align.
